(19) United States
(12) Patent Application Publication
(10) Pub. No.: US 2023/0117769 A1
(43) Pub. Date: Apr. 20, 2023

(54) INFORMATION PROCESSING APPARATUS AND INFORMATION PROCESSING METHOD

(71) Applicant: Fujitsu Limited, Kawasaki-shi (JP)

(72) Inventor: Kenichi KAWAGUCHI, Ebina (JP)

(73) Assignee: Fujitsu Limited, Kawasaki-shi (JP)

(21) Appl. No.: 18/082,612

(22) Filed: Dec. 16, 2022

Related U.S. Application Data
(63) Continuation of application No. PCT/JP2020/026580, filed on Jul. 7, 2020.

(51) Int. Cl. G06N 3/063

(52) U.S. Cl. CPC G06N 3/063

(57) ABSTRACT

In an information processing apparatus, an input unit converts first high-frequency signals into first radio waves and emits the first radio waves, a reservoir unit that is provided between the input unit and an output unit and that includes a plurality of semiconductor elements (in FIG. 1, one-dimensional semiconductors such as InAs semiconductor nanowires) for modulating the first radio waves by exhibiting non-linear response to the first radio waves outputs second radio waves obtained by modulating the first radio waves, and the output unit converts the received second radio waves into second high-frequency signals.

### CROSS-REFERENCE TO RELATED APPLICATION

This application is a continuation application of International Application PCT/JP2020/026580 filed on Jul. 7, 2020, which designated the U.S., the entire contents of which are incorporated herein by reference.

### FIELD

The embodiments discussed herein relate to an information processing apparatus and an information processing method.

### BACKGROUND

As one of computing systems for artificial intelligence (AI), a reservoir computing system, which is a type of recurrent neural network (RNN), is known (see, for example, Japanese Laid-open Patent Publication No. 2018-180701). The reservoir computing system includes a network-type device that is formed of non-linear elements and is called a reservoir.

There is a conventional technique of implementing a reservoir with complementary metal-oxide-semiconductor (CMOS) devices. In addition, there is a proposal of implementing a reservoir using a random network of carbon nanotubes (see, for example, Hirofumi Tanaka et al., “A molecular neuromorphic network device consisting of single-walled carbon nanotubes complexed with polyoxometalate”, Nature Communications volume 9, Article number: 2693, 2018).

Further, there is a conventional technique of communicating signals between neurons using radio waves in a neural network (for example, Japanese Laid-open Patent Publication No. H06-243117).

In a reservoir computing system, when an improvement in the integration density of an apparatus is achieved, it becomes possible to improve the performance of a reservoir, such as simplifying the configuration of a large-scale random network for the reservoir. In the case of implementing the reservoir with CMOS devices, however, it is difficult to improve the integration density due to an increase in the number of components and complexity of wiring. In addition, the conventional technique of implementing a reservoir using carbon nanotubes needs to electrically connect the carbon nanotubes so as to cause the carbon nanotubes to function as conductive wires, which makes it difficult to improve the integration density and thus to configure multiple terminal inputs and a large-scale random network.

### SUMMARY

According to one aspect, there is provided an information processing apparatus including: an input unit that converts a first high-frequency signal into a first radio wave and emits the first radio wave; an output unit that converts a received second radio wave into a second high-frequency signal; and a reservoir unit that is provided between the input unit and the output unit, that includes a plurality of semiconductor elements for modulating the first radio wave by exhibiting non-linear response to the first radio wave, and that outputs the second radio wave obtained by modulating the first radio wave.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of an information processing apparatus according to a first embodiment;

FIG. 2 illustrates an example of an information processing apparatus according to a second embodiment;

FIG. 3 illustrates an example of a transmitting antenna unit, reservoir unit, and receiving antenna unit;

FIG. 4 illustrates an example in which the reservoir unit has both a dense area of semiconductor elements and a sparse area of semiconductor elements;

FIG. 5 illustrates an example of the reservoir unit using nanowire diodes;

FIG. 6 illustrates an example of a weighting unit and learning unit; and

FIG. 7 is a flowchart illustrating an example flow of a computational process of the information processing apparatus according to the second embodiment.

### DESCRIPTION OF EMBODIMENTS

Hereinafter, embodiments will be described in detail with reference to the accompanying drawings.

### First Embodiment

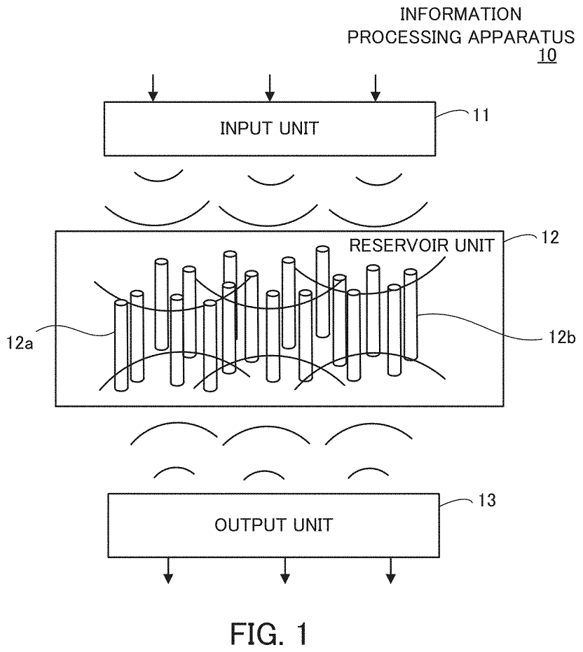

FIG. 1 illustrates an example of an information processing apparatus according to a first embodiment.

The information processing apparatus 10 according to the first embodiment functions as a reservoir computer, and includes an input unit 11, a reservoir unit 12, and an output unit 13.

The input unit 11 converts high-frequency signals into radio waves and emits the radio waves. For example, the high-frequency signals are microwave signals or terahertz-wave signals. The input unit 11 includes one or more antennas according to the number of high-frequency signals to be converted into radio waves, and converts the high-frequency signals into the radio waves with the antennas. In this connection, for example, a high-frequency signal has an amplitude based on the value of an input signal. The input signal is a signal based on a problem to be computed and is, for example, a signal with a value of 1 or 0, a sine wave signal, or another.

The reservoir unit 12 is provided between the input unit 11 and the output unit 13, and outputs radio waves obtained by modulating the radio waves emitted from the input unit 11. The reservoir unit 12 includes a plurality of semiconductor elements that modulate the radio waves emitted from the input unit 11 by exhibiting non-linear response to the radio waves.

For example, each of the plurality of semiconductor elements that exhibit the non-linear response is a one-dimensional semiconductor or a two-dimensional layered semiconductor.

As the one-dimensional semiconductors, nanowires (for example, indium arsenic (InAs) semiconductor nanowires) may be used. In addition, pn hetero nanowires (also called nanowire diodes), such as p-GaAs (gallium arsenic)/n-InAs, with stronger non-linearity than InAs semiconductor nanowires may be used as the one-dimensional semiconductors. Alternatively, carbon nanotubes may be used as the one-dimensional semiconductors.

As the two-dimensional layered semiconductors, graphene nanoribbons and others are used, for example.

FIG. 1 illustrates an example of using a plurality of one-dimensional semiconductors (one-dimensional semiconductors 12a and 12b and others) as the plurality of semiconductor elements of the reservoir unit 12.

The output unit 13 receives the radio waves (obtained by modulation) output from the reservoir unit 12, and converts the received radio waves into high-frequency signals. For example, the output unit 13 includes one or more antennas according to the number of high-frequency signals to be output, and converts the received radio waves into the high-frequency signals with the antennas. The output unit 13 outputs a computation result based on the amplitudes of the high-frequency signals. For example, the output unit 13 converts the plurality of high-frequency signals obtained by the plurality of antennas into direct current signals, weights each direct current signal by a weight value obtained by training, and outputs a value obtained by adding these as the computation result of the information processing apparatus 10. For example, the computation result is an inference result in the case where the problem to be computed is a problem to infer something, or is a classification result in the case where the problem to be computed is a problem to classify something.

With the information processing apparatus 10 as described above, the signal processing of the reservoir unit 12 that functions as a neural network using fixed values as the weight values (also called coupling coefficients) between neurons is performed using radio waves that propagate in a space. More specifically, high-frequency signals are converted into radio waves by the input unit 11, and the converted radio waves are modulated through non-linear response by the plurality of semiconductor elements of the reservoir unit 12 and are converted back to high-frequency signals by the output unit 13. This information processing apparatus 10 is equivalent to a reservoir computing device having wire connections. However, the information processing apparatus 10 does not need wiring in the reservoir unit 12, which makes it possible to improve the integration density with a simple process. It is thus expected to improve the performance of the reservoir computer, such as simplifying the configuration of a large-scale random network for it.

In addition, the plurality of semiconductor elements may be configured to have different sizes (for example, one-dimensional semiconductors may have different lengths in the long axis direction) (this may be achieved using manufacturing variance), or the reservoir unit 12 may be provided with an area where semiconductor elements are sparsely arranged and an area where semiconductor elements are densely arranged. This enables an increase in the diversity of the random network, so as to implement the reservoir computer with higher performance.

In addition, in the case of using one-dimensional semiconductors as the semiconductor elements, the antenna effect of the semiconductor elements themselves causes sufficient interaction between the semiconductor elements that are nodes of the random network and propagating radio waves, which enables the reservoir unit 12 to perform signal processing similar to that in the case of using network-type elements.

In this connection, reservoir computing performs training by adjusting weight values for output signals of a reservoir layer. Likewise, the above-described information processing apparatus 10 is able to perform training by adjusting the weight values for the direct current signals obtained by converting the high-frequency signals obtained from the radio waves output from the reservoir unit 12. A configuration example for the training will be described later.

### Second Embodiment

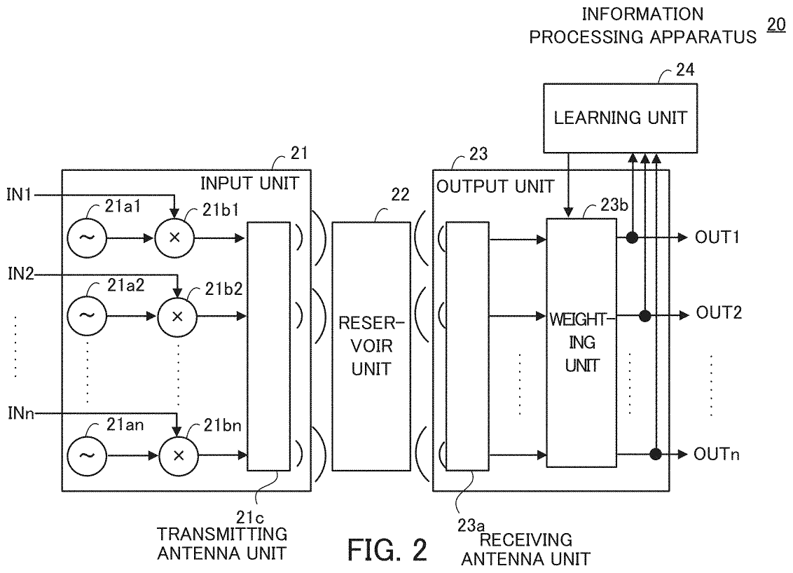

FIG. 2 illustrates an example of an information processing apparatus according to a second embodiment.

The information processing apparatus 20 of the second embodiment includes an input unit 21, a reservoir unit 22, an output unit 23, and a learning unit 24.

The input unit 21 includes high-frequency power sources 21a1, 21a2, . . . , 21an, multipliers 21b1, 21b2, . . . , 21bn, and a transmitting antenna unit 21c.

The high-frequency power sources 21a1 to 21an output high-frequency signals. The high-frequency signals output from the high-frequency power sources 21a1 to 21an have the same frequency. In this connection, the number of high-frequency power sources 21a1 to 21an may be one, and a high-frequency signal from one high-frequency power source may be supplied in common to the multipliers 21b1 to 21bn.

Each of the multipliers 21b1 to 21bn outputs the product of a received high-frequency signal and a corresponding one of input signals IN1, IN2, . . . , INn. Thereby, the strengths (amplitudes) of the n high-frequency signals output from the multipliers 21b1 to 21bn respectively reflect the input signals IN1 to INn.

The transmitting antenna unit 21c includes an antenna that converts the high-frequency signals output from the multipliers 21b1 to 21bn into radio waves and emits the radio waves.

In this connection, a plurality of antennas may be provided, and the number of antennas does not need to match the number of input signals IN1 to INn (the number of multipliers 21b1 to 21bn). For example, a high-frequency signal output from one of the multipliers 21b1 to 21bn may be input to the plurality of antennas, or high-frequency signals output from the plurality of multipliers may be input to one antenna. An example of the antenna will be described later.

The reservoir unit 22 outputs radio waves obtained by modulating the radio waves emitted from the antenna of the input unit 21. The reservoir unit 22 includes a plurality of semiconductor elements that modulate the radio waves emitted from the input unit 21 by exhibiting non-linear response to the radio waves. An example of the reservoir unit 22 will be described later.

The output unit 23 includes a receiving antenna unit 23a and a weighting unit 23b.

The receiving antenna unit 23a receives the radio waves modulated by the reservoir unit 22 and converts the received radio waves into high-frequency signals. For example, the output unit 23 has one or more antennas according to the number of high-frequency signals into which the received radio waves are converted, and converts the received radio waves into high-frequency signals with the antennas.

The weighting unit 23b weights direct current signals obtained by converting the high-frequency signals and outputs the weighted signals or signals by adding the plurality of weighted signals as output signals OUT1, OUT2, . . . , OUTn.

In this connection, the number of output signals OUT1 to OUTn does not need to match the number of antennas provided in the receiving antenna unit 23a. In addition, the number of output signals OUT1 to OUTn does not need to match the number of input signals IN1 to INn. For example, the number of output signals OUT1 to OUTn may be one.

The learning unit 24 obtains teacher data and adjusts the magnitude of the weighting performed by the weighting unit 23b on the basis of the teacher data and the output signals OUT1 to OUTn of the output unit 23.

Examples of the weighting unit 23b and learning unit 24 will be described later.

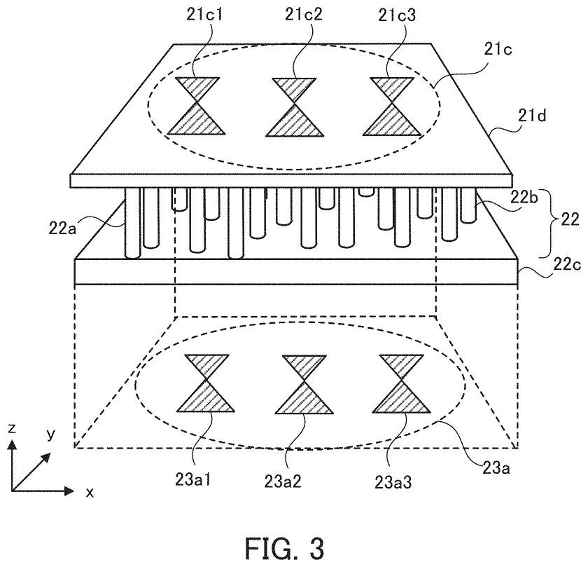

FIG. 3 illustrates an example of the transmitting antenna unit, reservoir unit, and receiving antenna unit.

The transmitting antenna unit 21c includes bowtie antennas 21c1, 21c2, and 21c3. Each bowtie antenna 21c1 to 21c3 is formed by a pair of electrodes whose triangles have apices facing each other. The bowtie antennas 21c1 to 21c3 are formed on a substrate 21d.

The use of the bowtie antennas 21c1 to 21c3 makes it possible to emit radio waves obtained by converting high-frequency signals to the reservoir unit 22 efficiently because of a bowtie antenna effect.

The reservoir unit 22 illustrated in FIG. 3 includes a plurality of InAs semiconductor nanowires (InAs semiconductor nanowires 22a and 22b and others, for example) as the plurality of semiconductor elements that exhibit non-linear response. For example, the plurality of InAs semiconductor nanowires are formed on a substrate 22c such as a silicon (Si) substrate so as to extend in the z direction by crystal growth.

In this connection, the InAs semiconductor nanowires may be arranged regularly on the substrate 22c, but may preferably be arranged randomly in order to increase the diversity of the random network.

Note that, in the semiconductor elements that exhibit non-linear response to high-frequency signals converted into radio waves, their strengths of the interactions with the high-frequency signals depend on their lengths in the long axis direction. As the interactions become stronger, the reservoir unit 22 has higher performance.

Especially, the length of a semiconductor element in the long axis direction is preferably greater than or equal to 1/10 the effective wavelength of a high-frequency signal (the value obtained by dividing the wavelength by the refractive index of the semiconductor element), because such a semiconductor element itself has a remarkable antenna effect and has a stronger interaction with the high-frequency signal.

In general, nanowires such as InAs semiconductor nanowires have a wire length of several μm to 100 μm. Assuming microwave and terahertz-wave high-frequency signals, such high-frequency signals have a wavelength of several hundred μm to several cm. Therefore, in the case of using nanowires, the longer in the long axis direction, the more preferred. Especially, in the case where the wire length in the long axis direction is greater than or equal to 1/10 the effective wavelength of a high-frequency signal, as described above, the nanowires themselves have a remarkable antenna effect. Therefore, for example, in the case where a minimum frequency of 250 GHz (a wavelength of 1200 μm) is set for the frequencies of the high-frequency signals, the wire lengths of the InAs semiconductor nanowires may be set to 1200/(3.5×10)=34 (μm) or more, considering that InAs has a refractive index of 3.5.

With this, the reservoir unit 22 with high performance may be implemented with fewer InAs semiconductor nanowires. For example, in the case of using InAs semiconductor nanowires with a wire length of 3.4 μm, the InAs semiconductor nanowires need to be formed with a density that is 10 times as high as that in the case with a wire length of 34 μm, in order to achieve the same performance.

The reservoir unit 22 is spatially separated from the input unit 21 including the transmitting antenna unit 21c by the substrate 21d, and is also spatially separated from the output unit 23 including the receiving antenna unit 23a by the substrate 22c.

In this connection, in the reservoir unit 22, a plurality of regions where semiconductor elements as described above are formed may be layered in the z direction. For example, a plurality of layers where InAs semiconductor nanowires are formed on the substrate 22c by crystal growth in the z direction may be layered in the z direction. This makes it possible to configure a large-scale random network.

In addition, in the reservoir unit 22, an area where semiconductor elements are sparsely arranged and an area where semiconductor elements are densely arranged may coexist.

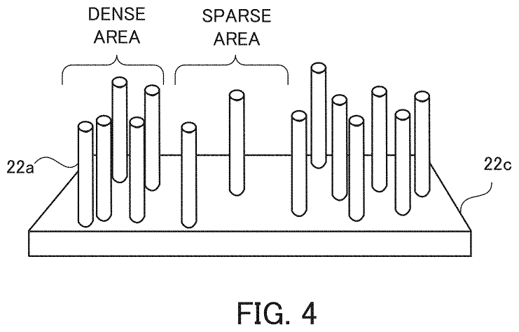

FIG. 4 illustrates an example in which the reservoir unit has both a dense area of semiconductor elements and a sparse area of semiconductor elements.

In the example of FIG. 4, an area where InAs semiconductor nanowires (InAs semiconductor nanowire 22a and others) are densely arranged and an area where InAs semiconductor nanowires are sparsely arranged coexist.

This enables an increase in the diversity of the random network, so as to implement the reservoir computer with higher performance.

Note that, in place of the InAs semiconductor nanowires, nanowire diodes of pn hetero junction type, such as p-GaAs/n-InAs, with stronger non-linearity than the InAs semiconductor nanowires may be used as the nanowires.

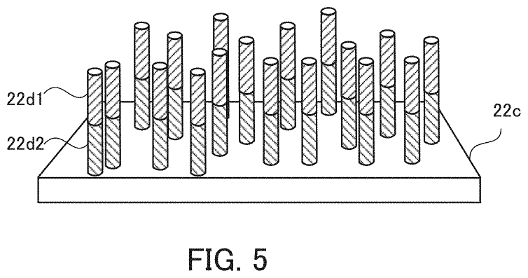

FIG. 5 illustrates an example of a reservoir unit using nanowire diodes.

The nanowire diodes are each formed by joining a p-type semiconductor 22d1 and an n-type semiconductor 22d2. For example, the p-type semiconductor 22d1 is p-type GaAs, whereas the n-type semiconductor 22d2 is n-type InAs.

The nanowire diodes exhibit strong non-linearity and therefore enable the reservoir unit 22 to have higher performance.

In this connection, carbon nanotubes may be used as an example of the one-dimensional semiconductors.

Referring to FIG. 3, the receiving antenna unit 23a includes bowtie antennas 23a1, 23a2, and 23a3. The bowtie antennas 23a1 to 23a3 are formed on the rear surface of the substrate 22c that has InAs semiconductor nanowires formed on the front surface thereof.

The use of the bowtie antennas 23a1 to 23a3 makes it possible to receive high-frequency signals converted into radio waves from the reservoir unit 22 efficiently because of a bowtie antenna effect.

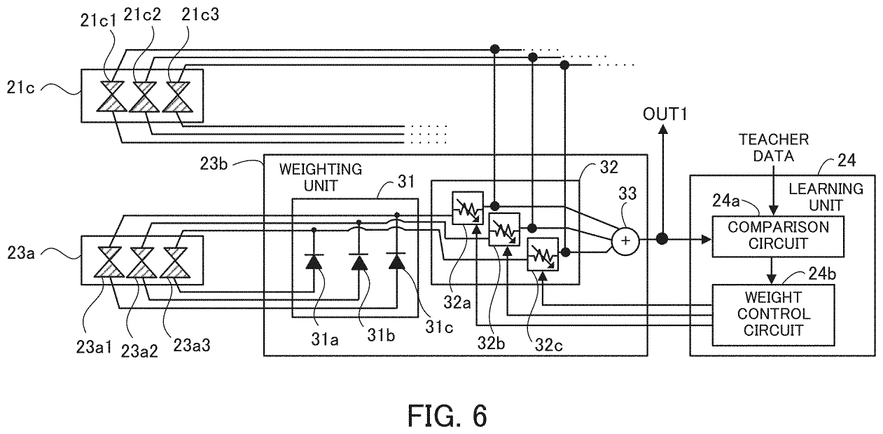

FIG. 6 illustrates an example of the weighting unit and learning unit.

In this connection, FIG. 6 illustrates an example of generating one output signal OUT1 from high-frequency signals obtained through conversion by three bowtie antennas 23a1 to 23a3, for simple description.

The weighting unit 23b includes a direct current (DC) conversion unit 31, weight adjustment unit 32, and an addition unit 33.

The DC conversion unit 31 converts high-frequency signals obtained by converting radio waves with the receiving antenna unit 23a, into direct current signals (direct-current voltage or current amplitude signals).

Referring to the example of FIG. 6, the DC conversion unit 31 includes diodes 31a, 31b, and 31c. The anode of the diode 31a is connected to one of the pair of electrodes of the bowtie antenna 23a3, and the cathode of the diode 31a is connected to the other of the pair of electrodes of the bowtie antenna 23a3. The anode of the diode 31b is connected to one of the pair of electrodes of the bowtie antenna 23a2, and the cathode of the diode 31b is connected to the other of the pair of electrodes of the bowtie antenna 23a2. The anode of the diode 31c is connected to one of the pair of electrodes of the bowtie antenna 23a1, and the cathode of the diode 31c is connected to the other of the pair of electrodes of the bowtie antenna 23a1. Direct current signals respectively output from the cathodes of the diodes 31a, 31b, and 31c are outputs of the DC conversion unit 31.

The weight adjustment unit 32 weights the direct current signals output from the DC conversion unit 31. The magnitude of the weighting is adjusted by the learning unit 24.

In FIG. 6, the weight adjustment unit 32 includes memristors (variable resistance memories) 32a, 32b, and 32c as an example of analog memories holding the magnitude of the weighting. The direct current signals output from the cathodes of the diodes 31a, 31b, and 31c are respectively weighted according to the magnitudes of the resistances of the memristors 32a, 32b, and 32c controlled by the learning unit 24.

The addition unit 33 outputs the result of adding the weighted direct current signals as the output signal OUT1, which is a computation result of the information processing apparatus 20.

In this connection, as illustrated in FIG. 6, for example, the outputs of the weight adjustment unit 32 or signals subjected to attenuation at a fixed rate by resistors, not illustrated, are respectively added to high-frequency signals that propagate through the signal lines connected to the bowtie antennas 21c1 to 21c3 provided at the input stage. With such a feedback loop, an input is made such that a past output is directly associated with the current input. For example, in training with time-series data, it is possible to perform the training so as to highly reflect the temporal correlation. That is, for a problem in which training for the temporal correlation dominates the performance, the use of the feedback loops makes it possible to achieve high speed training. In this connection, it is possible to activate or deactivate the feedback loops individually by using switches or the like, not illustrated.

For example, the weighting unit 23b as described above may be formed on the same plane as where the bowtie antennas 23a1 to 23a3 are formed on the substrate 22c illustrated in FIG. 3.

The learning unit 24 includes a comparison circuit 24a and a weight control circuit 24b. The comparison circuit 24a outputs a comparison result (for example, an error) of comparing received teacher data with the output signal OUT1.

On the basis of the comparison result, the weight control circuit 24b adjusts the magnitude of the weighting (for example, the magnitudes of the resistances of the memristors 32a, 32b, and 32c) in the weighting unit 23b so as to minimize the error.

In this connection, after the training is complete, the learning unit 24 is cut off from the weighting unit 23b by using a switch or the like, not illustrated.

The learning unit 24 may be a computer that is implemented by using a processor or the like that is a hardware component such as a central processing unit (CPU) or a digital signal processor (DSP). In this connection, the learning unit 24 may include an application specific electronic circuit such as an application specific integrated circuit (ASIC) or field programmable gate array (FPGA). The processor executes programs stored in a memory such as a random access memory (RAM) to control the magnitude of weighting on the basis of the comparison result of comparing the teacher data with the output signal OUT1.

The following describes a flow of a computational process of the information processing apparatus 20 according to the second embodiment.

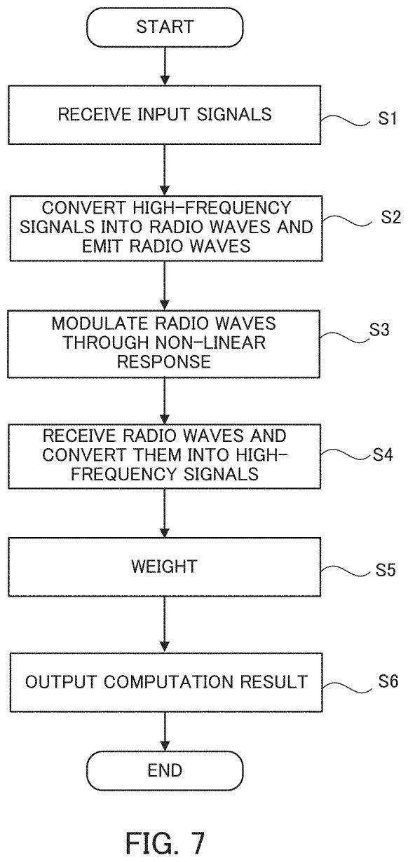

FIG. 7 is a flowchart illustrating an example flow of a computational process of the information processing apparatus according to the second embodiment.

The input unit 21 receives inputs of input signals IN1 to INn (step S1).

Then, in the input unit 21, the transmitting antenna unit 21c converts high-frequency signals reflecting the input signals IN1 to INn into radio waves and emits the radio waves (step S2).

The reservoir unit 22 modulates the radio waves emitted from the input unit 21 by exhibiting non-linear response to the radio waves (step S3).

In the output unit 23, the receiving antenna unit 23a receives the radio waves modulated by the reservoir unit 22 and converts the received radio waves into high-frequency signals (step S4).

In addition, the weighting unit 23b in the output unit 23 weights the direct current signals obtained by converting the high-frequency signals (step S5).

Then, the output unit 23 outputs the weighted signals or signals obtained by adding the plurality of weighted signals as the output signals OUT1 to OUTn that indicate a computation result (step S6). Then, the information processing apparatus 20 completes the computational process.

As with the information processing apparatus 10 of the first embodiment, the above-described information processing apparatus 20 eliminates the need of wiring in the reservoir unit 22, which makes it possible to improve the integration density with a simple process. It is thus expected to improve the performance of a reservoir computer, such as simplifying the configuration of a large-scale random network for it.

The above description is merely indicative of the principles of the present embodiments. A wide variety of modifications and changes may also be made by those skilled in the art. The present embodiments are not limited to the precise configurations and example applications indicated and described above, and all appropriate modifications and equivalents are regarded as falling within the scope of the embodiments as defined by the appended patent claims and their equivalents.

According to one aspect, the present disclosure makes it possible to improve the integration density of an information processing apparatus including a reservoir unit.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. An information processing apparatus comprising:
an input unit that converts a first high-frequency signal into a first radio wave and emits the first radio wave;
an output unit that converts a received second radio wave into a second high-frequency signal; and
a reservoir unit that is provided between the input unit and the output unit, that includes a plurality of semiconductor elements for modulating the first radio wave by exhibiting non-linear response to the first radio wave, and that outputs the second radio wave obtained by modulating the first radio wave.

2. The information processing apparatus according to claim 1, wherein each of the plurality of semiconductor elements is a one-dimensional semiconductor or a two-dimensional layered semiconductor.

3. The information processing apparatus according to claim 2, wherein the one-dimensional semiconductor is a nanowire diode.

4. The information processing apparatus according to claim 1, wherein, in the reservoir unit, an area where some of the plurality of semiconductor elements are sparsely arranged and an area where some of the plurality of semiconductor elements are densely arranged coexist.

5. The information processing apparatus according to claim 1, wherein the input unit or the output unit includes one or more bowtie antennas.

6. The information processing apparatus according to claim 1, wherein the output unit converts the second high-frequency signal into a direct current signal and weights the direct current signal.

7. The information processing apparatus according to claim 6, further comprising
a training unit that adjusts a magnitude of weighting for the direct current signal, based on teacher data, wherein
the input unit adds the weighted direct current signal to the first high-frequency signal.

8. An information processing method comprising:
converting, by an input unit, a first high-frequency signal into a first radio wave and emitting the first radio wave;
outputting, by a reservoir unit including a plurality of semiconductor elements for modulating the first radio wave by exhibiting non-linear response to the first radio wave, a second radio wave obtained by modulating the first radio wave; and
converting, by an output unit, the second radio wave received into a second high-frequency signal.
